(19) United States
(12) Patent Application Publication
(10) Pub. No.: US 2013/0112825 A1
(43) Pub. Date: May 9, 2013

(54) EXPANSION CARD RETAINING STRUCTURE

(71) Applicants: LUNG-CHUAN LIAO, NEW TAIPEI CITY (TW); HSIAO-MING CHEN, NEW TAIPEI CITY (TW); CHUN-CHI LIN, NEW TAIPEI CITY (TW)

(72) Inventors: LUNG-CHUAN LIAO, NEW TAIPEI CITY (TW); HSIAO-MING CHEN, NEW TAIPEI CITY (TW); CHUN-CHI LIN, NEW TAIPEI CITY (TW)

(73) Assignee: LITE-ON TECHNOLOGY CORPORATION, TAIPEI CITY (TW)

(21) Appl. No.: 13/355,515

(22) Filed: Jan. 21, 2012

(30) Foreign Application Priority Data
Nov. 7, 2011 (CN) 201120434868.4

(51) Int. Cl. H05K 7/14

(52) U.S. Cl. 248/221.11

(57) ABSTRACT

The present invention relates to a retaining structure for securing at least one expansion card (such as a Peripheral Component Interconnect, PCI card) on a motherboard. The retaining structure includes a frame member and a handle. The frame member has a main body, and the main body has at least one outer fixing portion and an inner fixing portion. The main body has a top piece and a connecting piece. The connecting piece is arranged away from the outer fixing portion and connected to the inner fixing portion. The handle is connected to the connecting piece. Upon mounting of the retaining structure, the distance between the handle and a base plate of a housing is less than the distance between the top piece and the base plate of the housing. This retaining structure may be easily dismounted in restricted space internal of the housing.

### BACKGROUND OF THE INVENTION

1. Field of the Invention

The present invention relates to a retaining structure for computer housing; more particularly, to a retaining structure for accommodating at least one computer expansion card.

2. Description of Related Art

An expansion card (such as a Peripheral Component Interconnect, PCI card) is typically mounted onto a housing of an electronic device by a frame structure. When manually detaching the frame, a user has to insert his or her fingers under the frame structure. With much inconvenience, the fingers are forced to operate in a confined space inside the housing.

Moreover, the person who is trying to dismount the frame often has a hard time seeing the frame itself, which is tightly disposed inside the housing with many other peripheral devices blocking the view. Furthermore, the restricted space defined between the frame and the surrounding electronic components often hinders the dismounting process.

### SUMMARY OF THE INVENTION

The present invention provides an expansion card retaining structure. The retaining structure offers structural and directional advantages such that the user can easily dismount the expansion card.

The retaining structure is used to secure at least one expansion card (such as a Peripheral Component Interconnect, PCI card) onto a motherboard. The motherboard is fixed to a base plate of a housing, while the connectors for integrated peripherals of the motherboard are exposed through a retaining plate of the housing. The base plate has a first fixing portion, and the retaining plate has at least one second fixing portion. The retaining structure comprises a frame member and a handle. The frame member has a main body, where the main body has at least one outer fixing portion and an inner fixing portion arranged on opposite ends thereof. The main body further has at least one top piece and at least one connecting piece. The connecting piece extends from the edge portion of the top piece toward the base plate of the housing. The connecting piece is arranged away from the outer fixing portion and connected to the inner fixing portion. The main body is dimensionally longer than the expansion card. When the retaining structure is installed, the outer fixing portion corresponds to the second fixing portion of the retaining plate, while the inner fixing portion corresponds to the first fixing portion of the base plate. Whereas the handle is connected to the connecting piece. When the retaining structure is installed, the distance between the handle and the base plate of the housing is less than the distance between the top piece and the base plate of the housing.

Based on the above, the handle of the retaining structure allows the user to easily and safely disengage the frame member without visual obstruction.

In order to further appreciate the characteristics and technical contents of the present invention, references are hereunder made to the detailed descriptions and appended drawings in connection with the present invention. However, the appended drawings are merely shown for exemplary purposes, rather than being used to restrict the scope of the present invention.

### BRIEF DESCRIPTIONS OF THE DRAWINGS

FIG. 1A is an assembled view for a first embodiment of the present invention.

FIG. 1B is an assembled view of the first embodiment taken from a different angle.

FIG. 2A is an exploded view of the first embodiment.

FIG. 2B is an exploded view of the first embodiment taken from a different angle.

FIG. 3 is an assembled view of the first embodiment, where a screw is used as a handle.

FIG. 4 is a schematic view showing the mounting/dismounting of the first embodiment.

FIG. 5A is an assembled view for a second embodiment of the present invention.

FIG. 5B is an assembled view of the second embodiment taken from a different angle.

FIG. 6A is an exploded view of the second embodiment.

FIG. 6B is an exploded view of the second embodiment taken from a different angle.

FIG. 7 is an assembled view of the second embodiment, where the screw is used as the handle.

FIG. 8 is an assembled view for a third embodiment of the present invention.

### DETAILED DESCRIPTIONS OF THE EMBODIMENTS

### First Embodiment

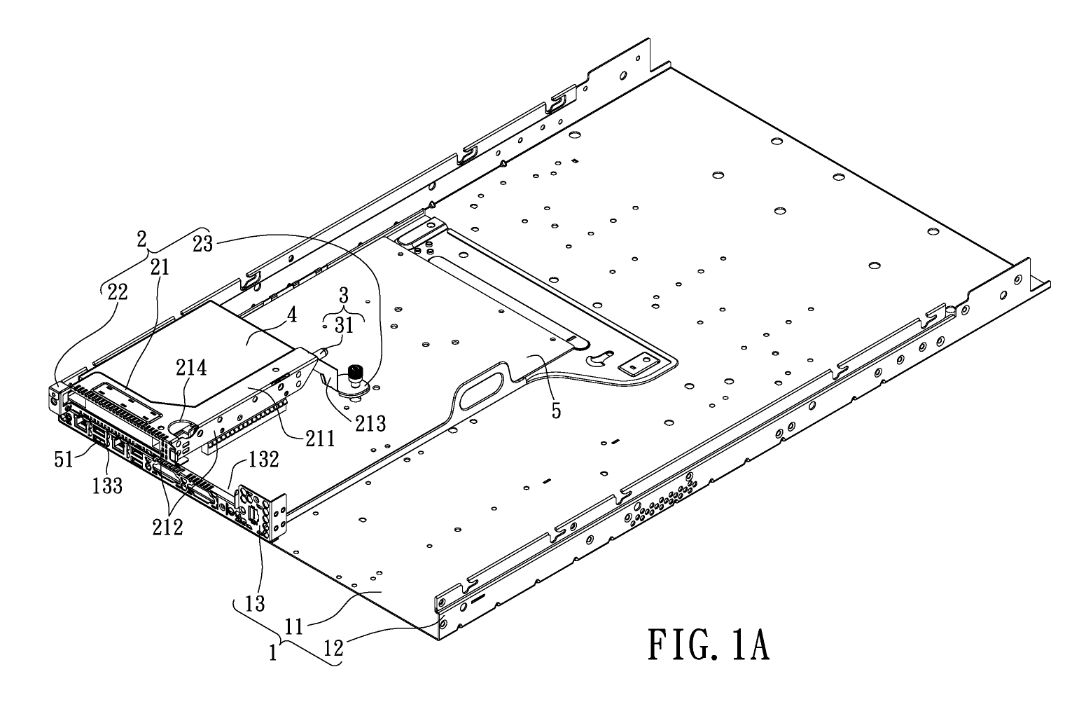

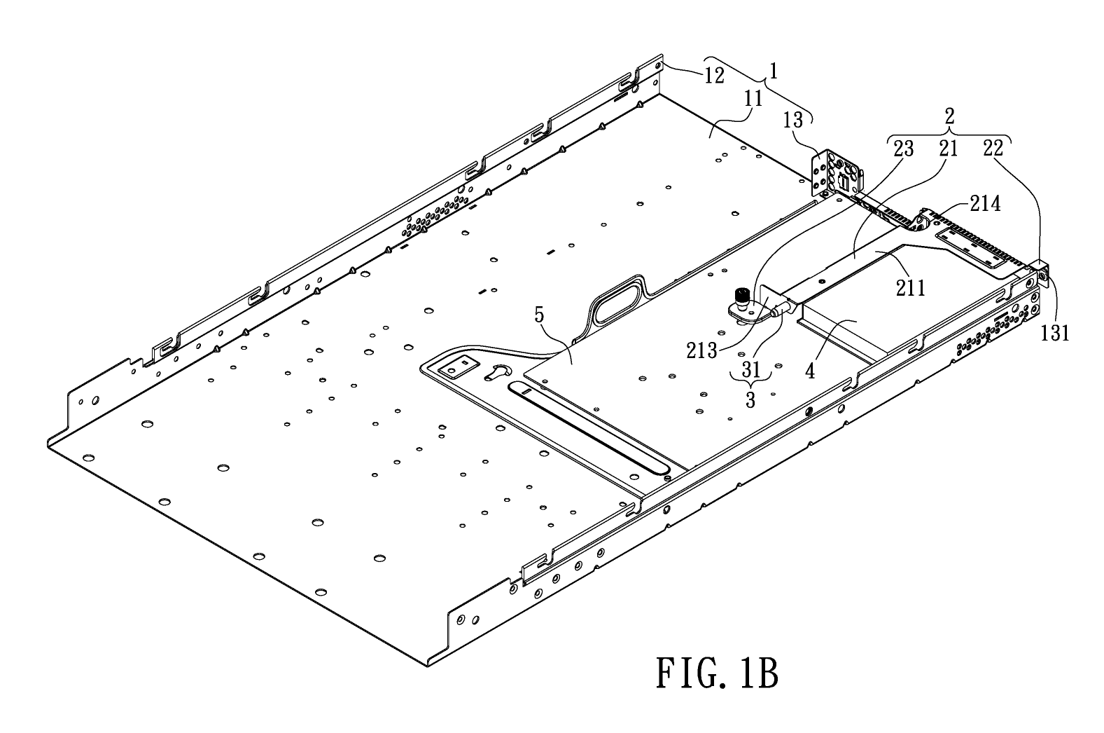

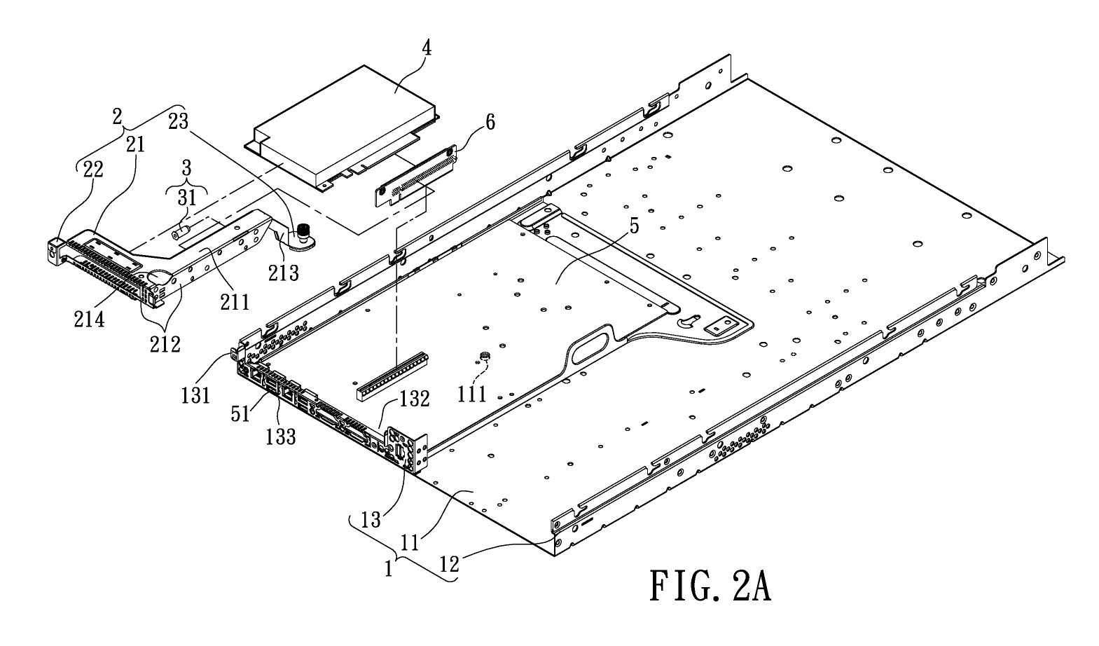

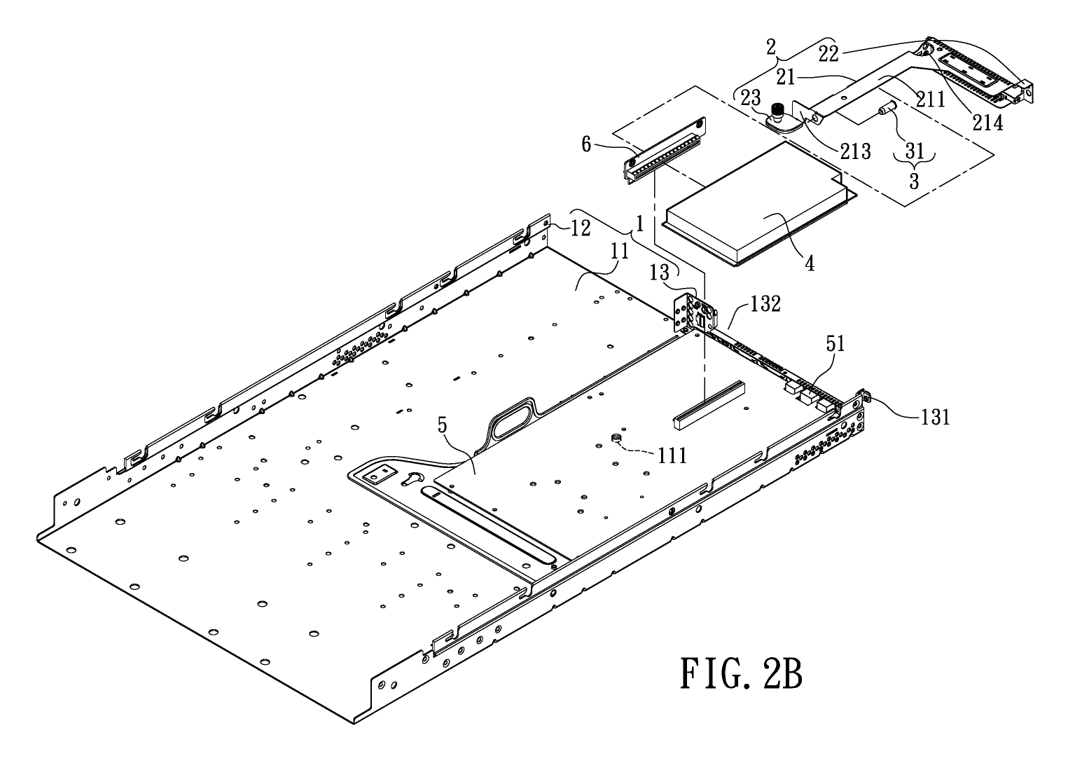

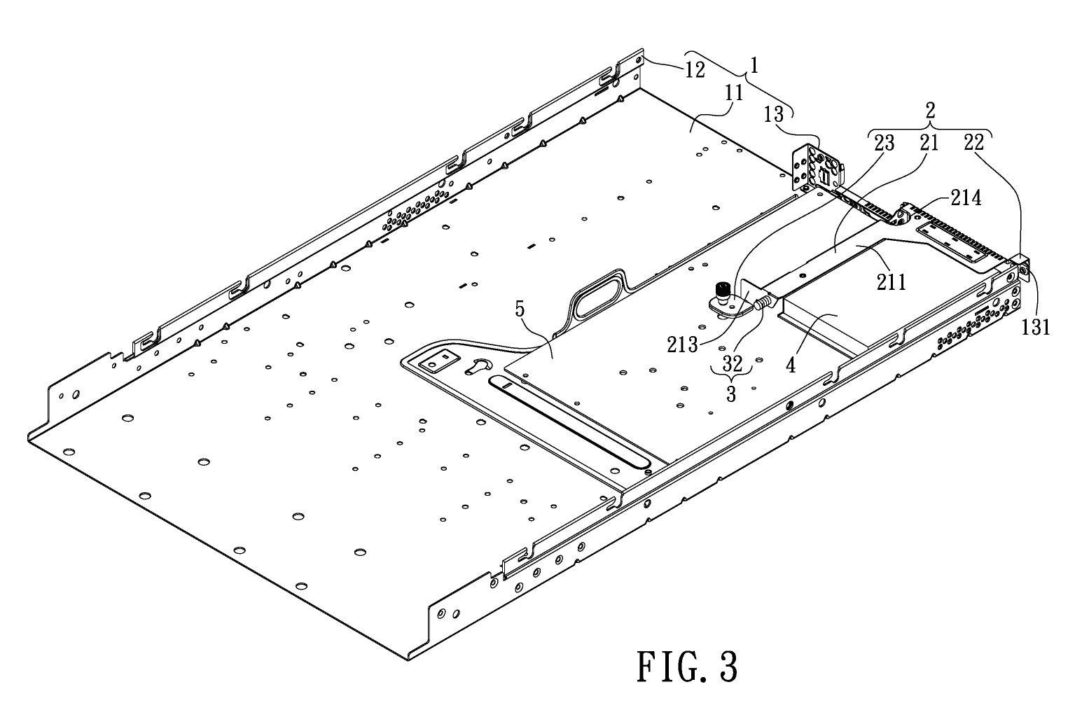

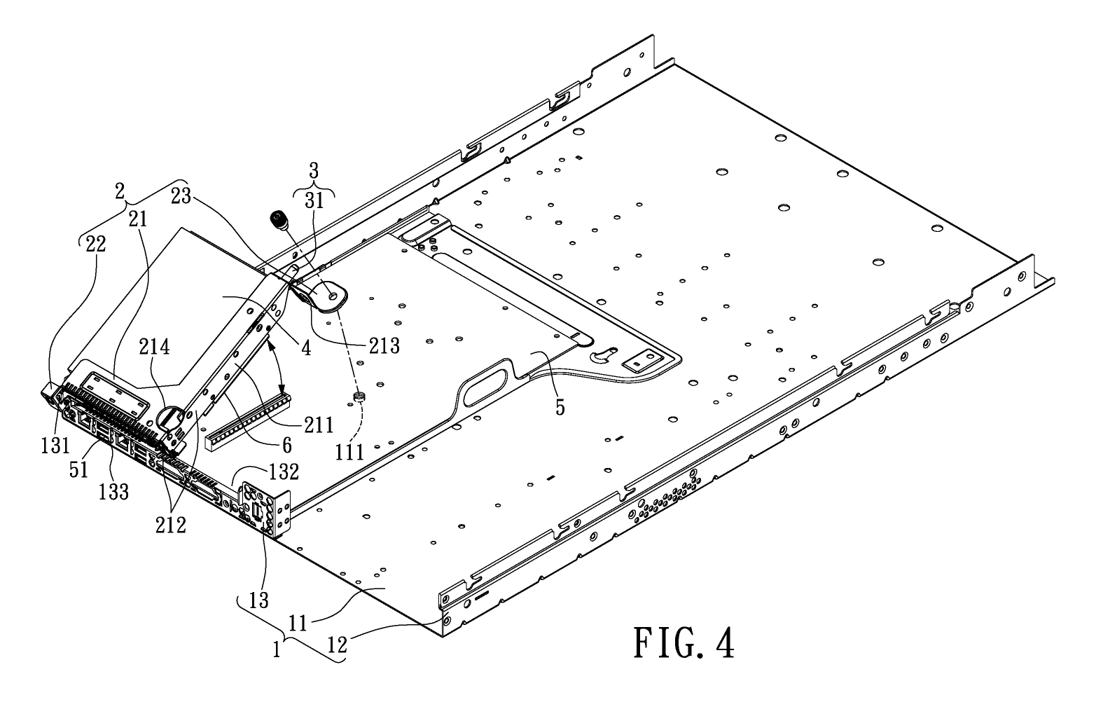

Please refer to FIGS. 1A˜4, which show an expansion card retaining structure for a first embodiment of the present invention. FIGS. 1A, 1B, and 3 are assembled views, while FIGS. 2A and 2B are exploded views, and FIG. 4 is a schematic view showing the mounting/dismounting of the retaining structure.

As shown in FIGS. 1A and 1B, the installed retaining structure is used to mount an expansion card 4 onto a motherboard 5. The motherboard 5 is fixed on a housing 1.

As shown in FIGS. 2A and 2B, the housing 1 has a base plate 11, a pair of extensions 12 bendingly extending from opposite edge portions of the base plate 11, and a protruding retaining plate 13 arranged on the base plate 11 and abutting one of the extensions 12. Furthermore, the base plate 11 has a first fixing portion 111.

With the orientation shown in the figures, the height of the retaining plate 13 is approximately the same as the extensions 12. The retaining plate 13 has a second fixing portion 131 adjacent to the corresponding extension 12. The retaining plate 13 further has a notch 132 and a plurality of ports 133 formed thereon. The motherboard 5 is fixed on the base plate 11 of the housing 1, where connectors 51 of the motherboard 5 for integrated peripherals are exposed through the ports 133 of the retaining plate 13.

The retaining structure of the instant embodiment comprises a frame member 2 and a handle 3. The following is the detail description of retaining structure upon installation on the housing 1.

The frame member 2 has a main body 21, where an outer fixing portion 22 and an inner fixing portion 23 are defined on opposite ends thereof.

The main body 21 is provided with a connecting piece 213, and together with the handle 3, provides a leverage to save effort spent on dismounting the retaining structure. The main body 21 receives the expansion card 4 and is longer than the longitudinal edge portion of the expansion card 4. That is, because the main body 21 is structurally configured to accommodate the expansion card 4, the special dimension of the accommodating portion defined by the main body 21 (e.g., the length) is preferably greater than that of an expansion card 4 to be retained.

The main body 21 has a substantially L-shaped top piece 211, a pair of side pieces 212, and the connecting piece 213. The side pieces 212 extend from the edge portions of the top piece 211 toward the base plate 11 of the housing 1. The connecting piece 213 extends from one end of the top piece 211 toward the base plate 11 of the housing 1. The connecting piece 213 is arranged away from the outer fixing portion 22 and connected to the inner fixing portion 23. An access hole 214 is formed on the right-angled portion of the L-shaped top piece 211.

The side piece 212 away from the connecting piece 213 of the main body 21 is received in the notch 132 of the retaining plate 13. Thus, the main body 21 can be disposed on the retaining plate 13. The outer fixing portion 22 is extended from one end of the side piece 212 adjacent to the retaining plate 13. Specifically, the outer fixing portion 22 is arranged to correspondingly align/engage the second fixing portion 131 of the retaining plate 13. The inner fixing portion 23, which extends from one end of the connecting piece 213, is arranged to correspondingly align the first fixing portion 111 of the base plate 11.

For the instant embodiment, the outer fixing portion 22 and the inner fixing portion 23 are secured to the second fixing portion 131 and the first fixing portion 111 of the housing 1, respectively, by a fastening means but are not restricted thereto.

Furthermore, the technique used to electrically connect the expansion card 4 and the motherboard 5 will be discussed as follows. However, it is to be noted that the exact implementation should not be restricted thereto.

An adapter 6 can be arranged on the inner surface of the corresponding side piece 212 away from the outer fixing portion 22. This adapter 6 serves as a coupler between the motherboard 5 and the expansion card 4. Thereby, when the expansion card 4 is mounted on the main body 21, the expansion card 4 is electrically connected to the motherboard 5 through the adapter 6.

The handle 3 is substantially tubular in shape and perpendicularly connected to the connecting piece 213. For the instant embodiment, the handle 3 is a rivet-like cylindrical member 31 arranged on the connecting piece 213. However, in practice, the type of the handle 3 is not restricted, which may be a screw 32 bolted to the connecting piece 213 (as shown in FIG. 3).

Furthermore, the housing 1 is restrained from extending beyond a certain height. Accordingly, to receive the retaining structure by the allowable internal space of the housing 1, the distance between the handle 3 and the base plate 11 of the housing 1 is less than the distance between the top piece 211 of the main body 21 and the base plate 11 of the housing 1.

The descriptions provided above are for mounted retaining structure. Meanwhile, the installation or dismounting of the retaining structure is illustrated in FIG. 4 and discussed hereinbelow.

To mount the retaining structure, the user may first arrange the expansion card 4 on the frame member 2. Then, the outer fixing portion 22 is abutted against the second fixing portion 131.

Next, the user can grip the handle 3 and move the inner fixing portion 23 pivotally toward the first fixing portion 111, where the abutment between the outer fixing portion 22 and the second fixing portion 131 is taken as a pivot point.

Then, the adapter 6 is inserted in the motherboard 5. The inner fixing portion 23 is aligned with and secured to the first fixing portion 111, while the outer fixing portion 22 is secured to the second fixing portion 131.

During the mounting process, the user may also use the access hole 214 to hold the main body 21 for mounting.

To dismount the retaining structure, in other words, to separate the expansion card 4 mounted frame member 2 from the housing 1, the user can first disengage the inner fixing portion 23 and the outer fixing portion 22 from the housing 1.

Next, the user can pivotally lift the handle 3 in a direction away from the base plate 11 of the housing 1, using the abutment between the outer fixing portion 22 and the second fixing portion 131 of the housing 1 as the pivot point, thus disengaging the adapter 6 from the motherboard 5.

Likewise, during the dismounting process, the user may use the access hole 214 for holding the main body 21 to better remove the retaining structure.

Moreover, the handle 3 may be embossed or applied with coloration (not shown) for visual distinction.

### Second Embodiment

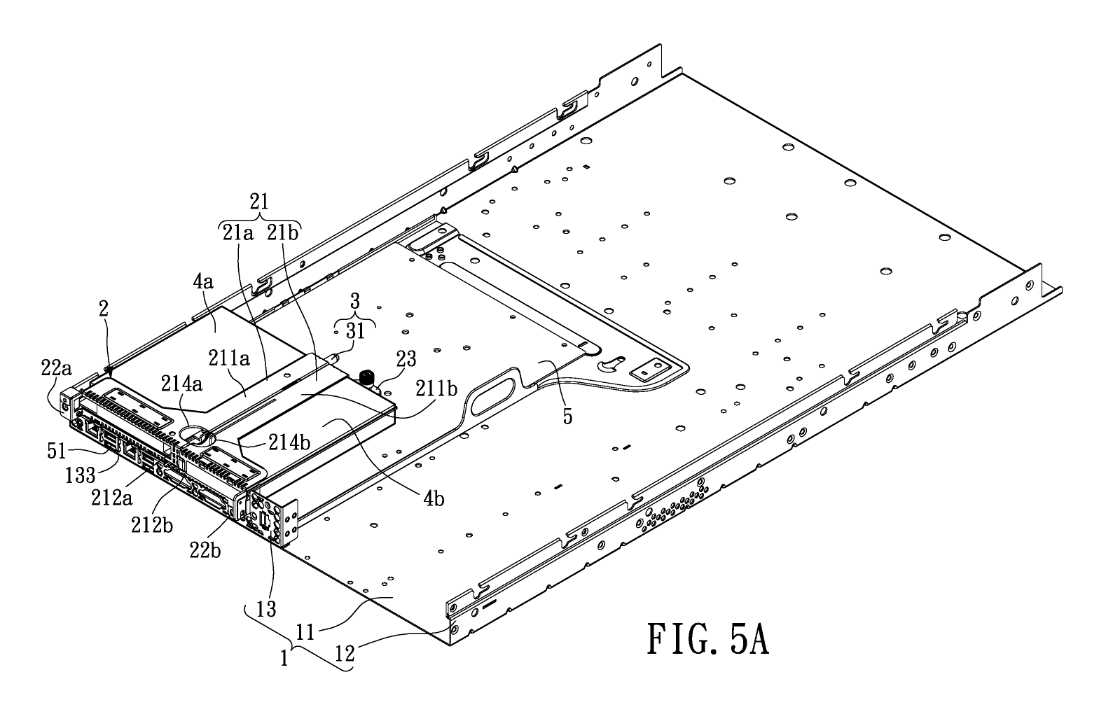

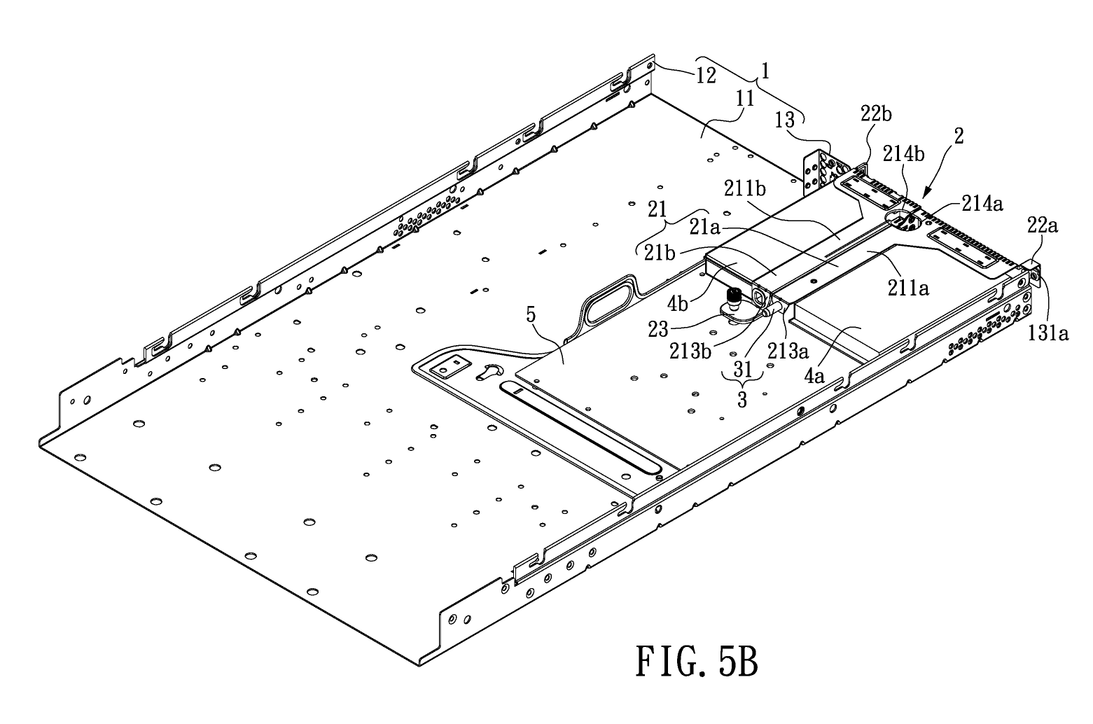

Please refer to FIGS. 5A to 7, which show a retaining structure for a second embodiment of the instant disclosure. This embodiment differs from the previous embodiment regarding to the retaining plate 13 of the housing 1 and the main body 21.

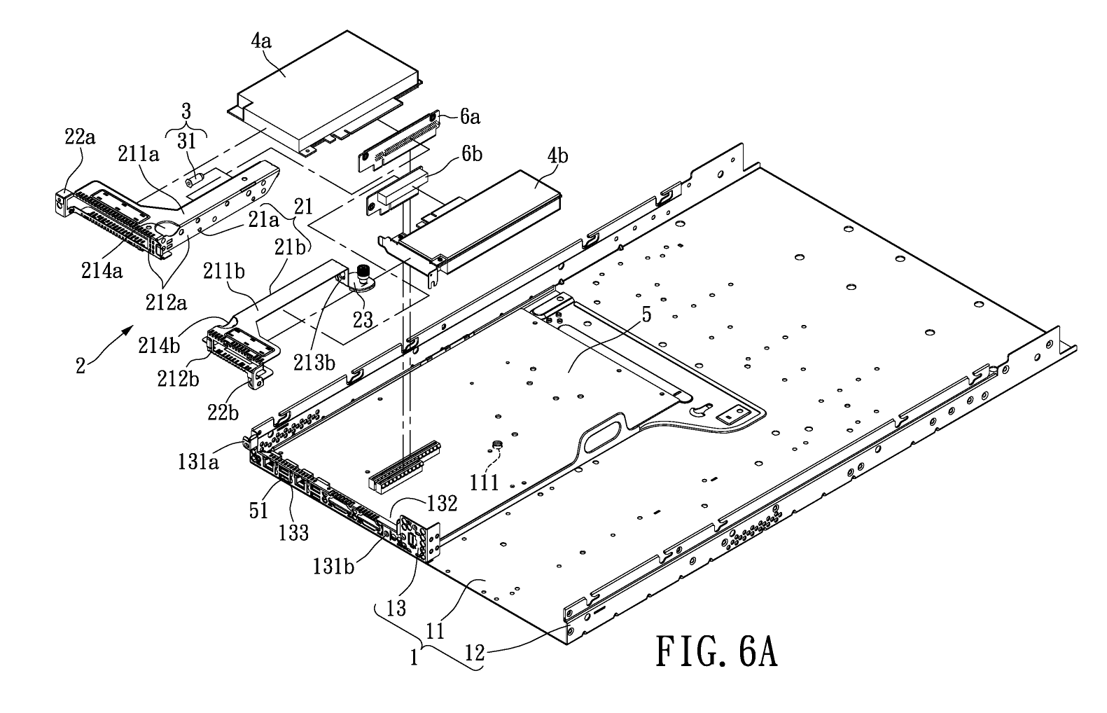

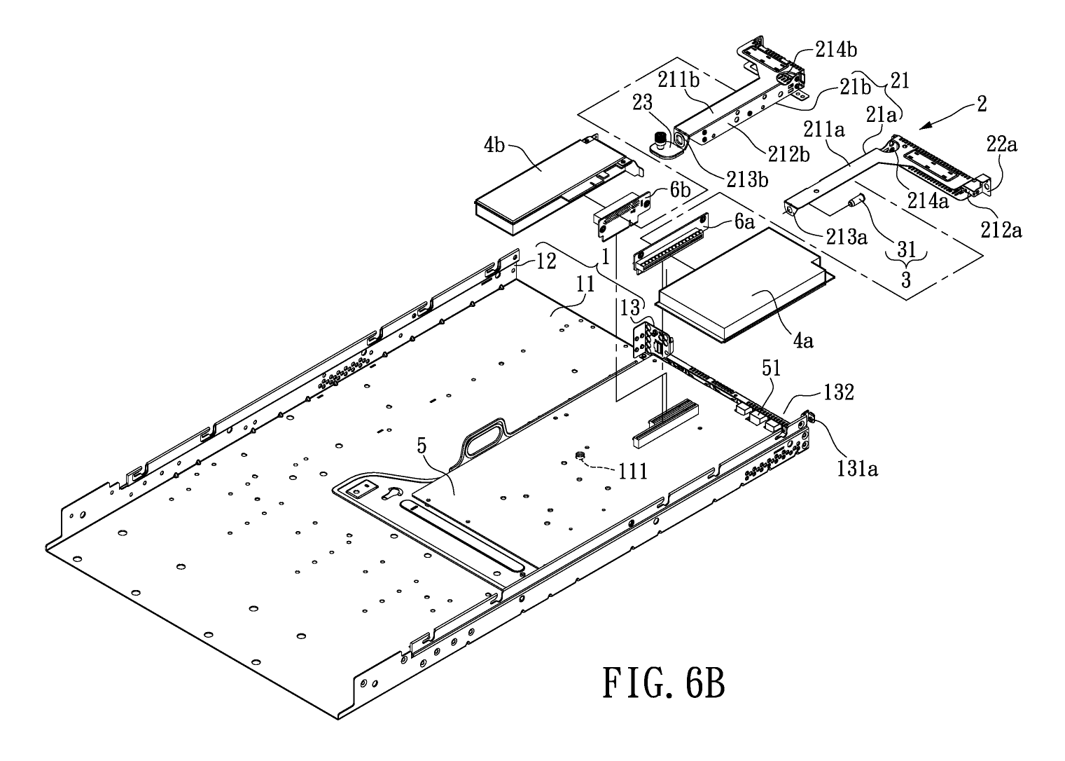

As shown in FIG. 6A, the retaining plate 13 of the housing 1 has two second fixing portions 131a and 131b. The main body 21 includes a first sub-body 21a and a second sub-body 21b adjacently arranged to each other. The first and second sub-bodies 21a and 21b are both structurally similar to the main body 21 in the first embodiment. The descriptions provided hereinafter are for the retaining structure arranged at mounted state.

The first sub-body 21a has an outer fixing portion 22a and the second sub-body 21b has an outer fixing portion 22b, where the first and second sub-bodies 21a and 21b are interconnected. The inner fixing portion 23 is formed on one end of the second sub-body 21b away from the outer fixing portion 22b.

The first and second sub-bodies 21a and 21b are used to secure expansion cards 4a, 4b, respectively. The first and second sub-bodies 21a and 21b are arranged on the outer surfaces of the expansion cards 4a and 4b, respectively. The first and second sub-bodies 21a and 21b are greater in length than the edge portions of the expansion cards 4a and 4b, respectively. In other words, the first and second sub-bodies 21a and 21b are structurally configured to accommodate the expansion cards 4a and 4b, where the accommodating portions of the first and second sub-bodies 21a and 21b are greater in length than the expansion cards 4a and 4b, respectively.

More specifically, as shown in FIGS. 6A and 6B, the first sub-body 21a has a top piece 211a, a pair of side pieces 212a, and a connecting piece 213a, while the second sub-body 21b has a top piece 211b, a pair of side pieces 212b, and a connecting piece 213b.

The top piece 211a of the first sub-body 21a and the top piece 211b of the second sub-body 21b are substantially L-shaped. As illustrated in FIG. 5B, the top pieces 211a and 211b cooperatively form a T-shaped structure.

For the first sub-body 21a, the side pieces 212a are extended from the edge portions of the L-shaped top piece 211a toward the base plate 11. For the second sub-body 21b, the side pieces 212b are extended from the edge portions of the L-shaped top piece 211b toward the base plate 11.

The connecting piece 213a is extended from one end of the top piece 211a toward the base plate 11, while the other connecting piece 213b is extended from one end of the top piece 211b toward the base plate 11. The connecting pieces 213a and 213b are arranged away from the outer fixing portions 22a and 22b, respectively. The connecting piece 213b of the second sub-body 21b is connected to the inner fixing portion 23.

For the first sub-body 21a, the corresponding side piece 212a away from the connecting piece 213a is received by the notch 132 of the retaining plate 13. Similarly, for the second sub-body 21b, the corresponding side piece 212b away from the connecting piece 213b is also received by the notch 132 of the retaining plate 13. Thus, the first and second sub-bodies 21a and 21b are arranged on the retaining plate 13. The outer fixing portions 22a and 22b are extended from the side pieces 212a and 212b adjacent to the retaining plate 13, respectively. The outer fixing portions 22a and 22b correspond to the second fixing portions 131a and 131b of the retaining plate 13, respectively. The inner fixing portion 23 extends from one end of the connecting piece 213b and corresponds to the first fixing portion 111 of the base plate 11.

For the instant embodiment, the outer fixing portions 22a and 22b are secured to the second fixing portions 131a and 131b of the housing 1, respectively, by a fastening means but are not restricted thereto. Whereas the inner fixing portion 23 is secured to the first fixing portion 111 of the housing 1.

Furthermore, recess holes 214a and 214b are formed on the right-angled portions of the top piece 211a of the first sub-body 21a and the top piece 211b of the second sub-body 21b, respectively. As shown in FIG. 5B, the access hole 214a of the first sub-body 21a and the access hole 214b of the second sub-body 21b are in communication with each other.

Furthermore, the technique used to electrically connect the expansion cards 4a and 4b with the motherboard 5 is discussed hereinbelow, but is not restricted thereto.

Adapters 6a and 6b are arranged on the inner surfaces of the side pieces 212a and 212b away from the outer fixing portions 22a and 22b of the first and second sub-bodies 21a and 21b, respectively. The adapters 6a and 6b serve as couplers between the motherboard 5 and the expansion cards 4a and 4b, respectively. When the expansion cards 4a and 4b are mounted on the first and second sub-bodies 21a and 21b, respectively, the adapters 6a and 6b provide electrical connections between the expansion cards 4a and 4b and the motherboard 5.

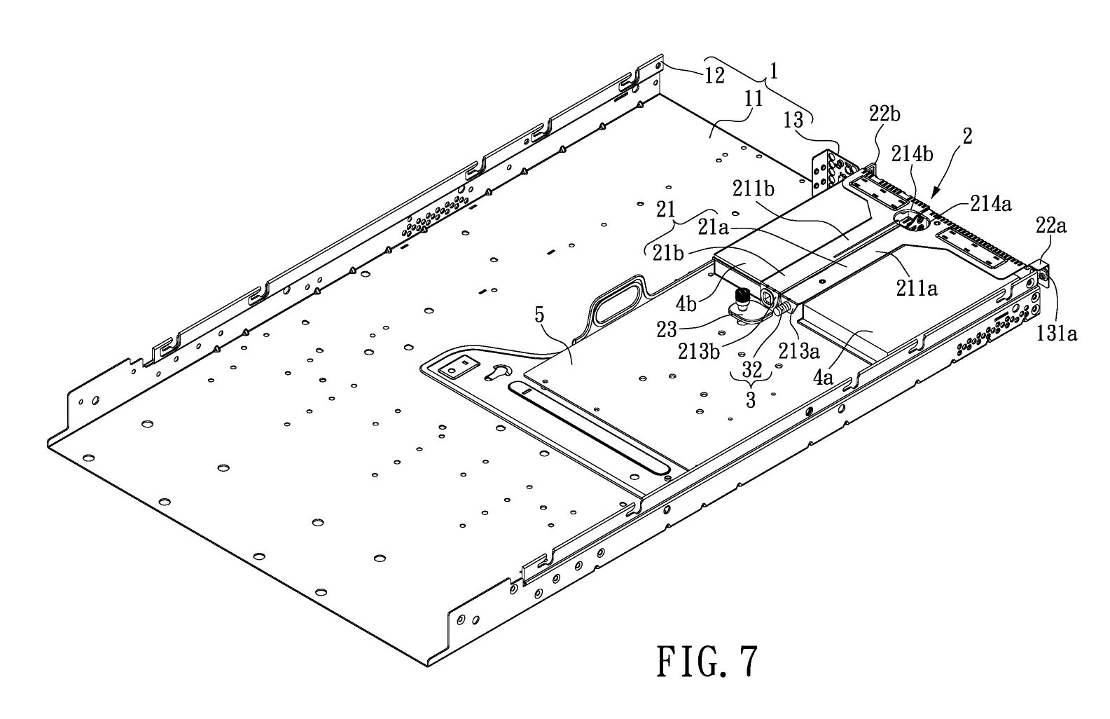

The handle 3 is substantially tubular shaped and perpendicularly connected to the connecting piece 213a. For the instant embodiment, the handle 3 is a rivet-like cylindrical member 31 arranged on the connecting piece 213a. However, in practice, the type of the handle 3 is not restricted, which may be a screw 32 bolted to the connecting piece 213a (as shown in FIG. 7). This handle 3 may also be connected to the connecting piece 213b (not shown).

Furthermore, the distance between the handle 3 and the base plate 11 of the housing 1 is less than the distance between the top piece 211a of the first sub-body 21a and the base plate 11 of the housing 1.

For the instant embodiment, the descriptions provided above are for the mounted retaining structure. Meanwhile, the installation or dismounting of the retaining structure is similar to the previous embodiment as illustrated in FIG. 4, therefore no further descriptions are provided herein.

### Third Embodiment

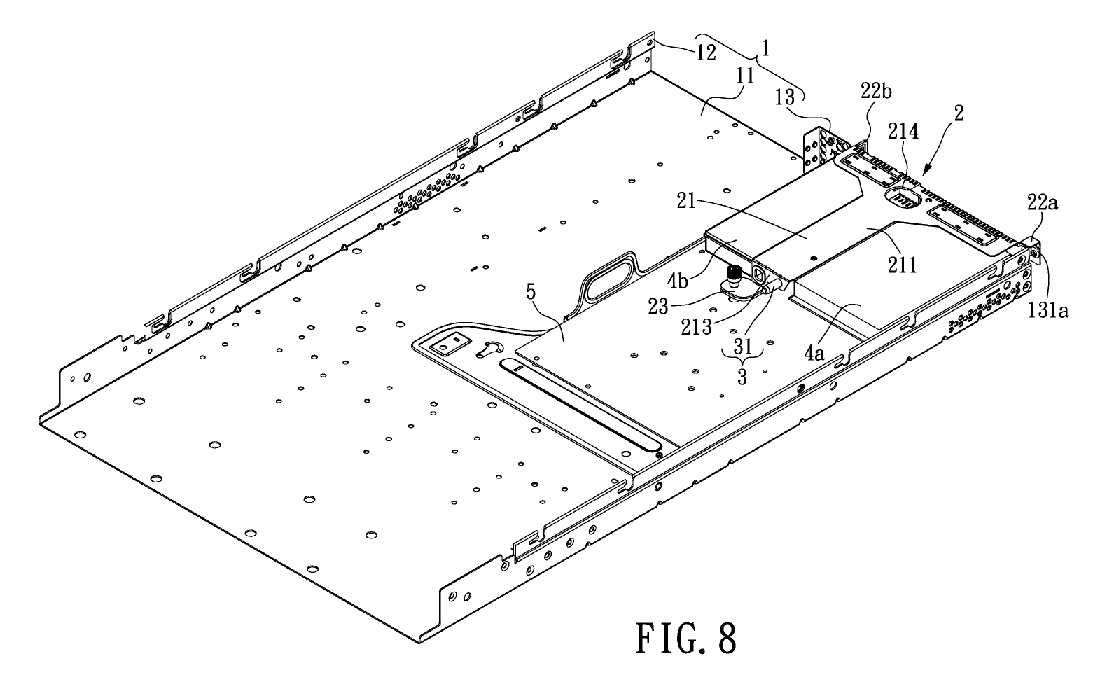

Please refer to FIG. 8, which shows a retaining structure for a third embodiment of the instant disclosure. This embodiment is similar to the second embodiment. However, the T-shaped main body 21 of this embodiment is integrally formed in one piece. In other words, the second sub-body 21b is extended from the first sub-body 21a in forming the main body 21.

For the instant embodiment, the connecting piece 213 extends from the edge portion of the top piece 211 in a direction toward the base plate 11 of the housing 1, where the connecting piece 213 is away from the outer fixing portions 22a and 22b.

### ADVANTAGES

Based on the above, the inclusion of the handle 3 allows the user to easily and safely install/dismount the retaining structure in restricted space without visual obstruction.

In addition, the handle 3 may be embossed or applied with coloration (not show) for visual distinction and better touch feel.

The descriptions illustrated supra set forth simply the preferred embodiments of the present invention; however, the characteristics of the instant disclosure are by no means restricted thereto. All changes, alternations, or modifications conveniently considered by those skilled in the art are deemed to be encompassed within the scope of the present invention delineated by the following claims.

What is claimed is:

1. An expansion card retaining structure for retaining at least one expansion card on a motherboard, the motherboard being secured to a base plate of a housing, the mother board having a plurality of peripheral connectors exposed through a retaining plate of the housing, the base plate having a first fixing portion, the retaining plate having at least one second fixing portion, the retaining structure comprising:
a frame member having a main body, wherein the main body has at least one outer fixing portion and an inner fixing portion formed on opposite ends thereof,
wherein the main body has at least one top piece and at least one connecting piece, the connecting piece being extended from the edge portion of the top piece in a direction toward the base plate,
wherein the connecting piece is arranged away from the outer fixing portion and connected to the inner fixing portion,
wherein the main body is longer than the longitudinal edge portion of the expansion card,
wherein when the retaining structure is arranged at mounted state, the outer fixing portion corresponds to the second fixing portion and the inner fixing portion corresponds to the first fixing portion of the base plate; and
a handle connected to the connecting piece, wherein when the retaining structure is arranged in a mounted state, the distance between the handle and the base plate of the housing is less than the distance between the top piece and the base plate of the housing.

2. The retaining structure of claim 1, wherein the handle is tubular shaped and perpendicularly connected to the connecting piece of the frame member.

3. The retaining structure of claim 1, wherein the top piece of the main body is substantially L-shaped and having an access hole formed on the right-angled portion thereof.

4. The retaining structure of claim 1, wherein the main body includes a first sub-body and a second sub-body interconnected for securing respective expansion card, and wherein the first and second sub-bodies each has one outer fixing portion, while the inner fixing portion extends from the second sub-body.

5. The retaining structure of claim 4, wherein the second sub-body extends from the first sub-body.

6. The retaining structure of claim 4, wherein the first and second sub-bodies each have one substantially L-shaped top piece, and wherein the top pieces of the first and second sub-bodies cooperatively form a T-shaped structure.

7. The retaining structure of claim 6, wherein an access hole is formed on the right-angled portion of each top piece of the first and second sub-bodies, and wherein the access holes are in communication with each other.

8. The retaining structure of claim 1, wherein the handle is fastened to the connecting piece.

9. The retaining structure of claim 1, wherein the handle is riveted to the connecting piece.
